(19) United States
(12) Patent Application Publication
(10) Pub. No.: US 2026/0173597 A1
(43) Pub. Date: Jun. 18, 2026

(54) MICRO LIGHT-EMITTING DIODE WITH DIELECTRIC FRAME AND PREPARATION METHOD THEREOF

(71) Applicant: Hsiao Lei WANG, Taoyuan City, Taiwan (CN)

(72) Inventors: Hsiao Lei WANG, Taoyuan City, Taiwan (CN); Neng Tai SHIH, New Taipei City, Taiwan (CN); Kao Mei SUNG, Taoyuan City, Taiwan (CN)

(21) Appl. No.: 19/114,449

(22) PCT Filed: Sep. 26, 2023
(86) PCT No.: PCT/CN2023/121427

§ 371 Date: Mar. 2, 2026

(30) Foreign Application Priority Data
Oct. 8, 2022 (CN) 202211220590.X

(51) Int. Cl. H10H 20/85; H10H 20/01; H10H 20/812; H10H 20/816; H10H 20/825

(52) U.S. Cl. CPC H10H 20/8504; H10H 20/01335; H10H 20/812; H10H 20/816; H10H 20/825

(57) ABSTRACT

The present invention provides a micro light-emitting diode with a dielectric frame, where an n-type doped layer is epitaxially formed on an epitaxial substrate; a dielectric frame is formed on the epitaxial substrate or the n-type doped layer; a multi-quantum well layer is grown within the dielectric frame and located on the n-type doped layer; a p-type doped layer is grown within the dielectric frame and located on the multi-quantum well layer; a protective layer covers the dielectric frame and the transparent current spreading layer; and first and second metal electrodes are connected to the p-type doped layer and the n-type doped layer.

### CROSS-REFERENCE TO RELATED APPLICATIONS

The present disclosure is a national phase entry of International Patent Application No. PCT/CN2023/121427, filed on Sep. 26, 2023, which claims priority to Chinese Patent Application No. 202211220590.X, filed on Oct. 8, 2022. International Patent Application No. PCT/CN2023/121427 and Chinese Patent Application No. 202211220590.X are incorporated herein by reference.

### TECHNICAL FIELD

The present invention relates to a micro light-emitting diode structure with a dielectric frame and a preparation method thereof.

### BACKGROUND

With the progress of the times, displays have become lighter and more power-efficient. The mainstream technology of displays has shifted from emerging OLED displays to actively investing in micro light-emitting diode (micro LED) displays. Micro LED displays, due to their various advantages such as self-luminescence, low power consumption, fast response time, high brightness, ultra-high contrast, wide color gamut, wide viewing angle, ultra-thinness, long service life, and adaptability to various working temperatures, have the potential to become the mainstream technology of next-generation displays under the leadership of international leading manufacturers and the active participation of the industry. Micro LED technology reduces the size of conventional LEDs from the millimeter (10⁻³ m) level to below 100 micrometers (10⁻⁶ m), which is 1% of the original LED volume. However, in the production and assembly process, massive transfer technology is required to transfer the micron-level RGB tricolor micro LED dies grown on an epitaxial substrate (also known as a native substrate or homogeneous substrate) to a display substrate (also known as a target substrate). The RGB pixels are arranged in a matrix and their brightness is controlled through addressing to achieve full color, thus forming a complete micro LED display.

Therefore, considering the complexity, yield, and output efficiency issues in the massive transfer process, a key challenge and major concern are formed. Due to the tiny size of the epitaxial and diced dies, accurately transferring millions of micron-level micro LED dies to the correct positions on the display substrate becomes a technical barrier for the industry.

To overcome the above massive transfer problem, there have been proposals to manufacture RGB three-color LED elements or at least two of them on the same epitaxial substrate and lay them out based on product requirements. The applicant of this application has also proposed related prior cases. In the manufacturing process of micro LED displays, red, green, and blue (RGB) three-primary-color light-emitting diodes are required to form the unit pixels. The current main manufacturing technology needs to mix nitride and phosphide light-emitting diodes to meet the demand for the three primary colors. When different material systems of light-emitting diodes are mixed, different heating and decay characteristics directly affect the quality of image presentation; different electrical drive characteristics directly lead to the complexity of the display module drive design. Therefore, achieving direct-emitting RGB (red, green, blue) primary-color light-emitting diodes within the same material system not only helps resolve the above problem but also eliminates the need for color-conversion mechanisms such as phosphors. This reduces manufacturing complexity and energy efficiency losses caused by conversion processes, thereby significantly benefiting the development of micro LED technology.

Indium gallium nitride In_{X}Ga_{1-X}N epitaxial materials are currently one of the material systems for making mainstream blue light-emitting diodes. Theoretically, the indium gallium solid solution ratio can be used to cover the entire visible light emission range. Indium gallium nitride, benefiting from its direct energy gap characteristic, is also expected to have good light emission performance, especially since blue light mass production technology is mature. Therefore, it has received more attention than other material systems and has great potential in making direct red, green, and blue light-emitting diodes (RGB direct LEDs) with similar control conditions and excellent performance. However, limited by the substrate, the red light-emitting diodes of the In_{X}Ga_{1-X}N epitaxial material system currently face technical bottlenecks. To achieve an appropriate emission wavelength for red light, the In content ratio of the In_{X}Ga_{1-X}N epitaxial material needs to be increased. In the epitaxial manufacturing process, the In content must be increased by lowering the epitaxial temperature, but this faces obstacles such as the epitaxial quality not meeting application specifications. Therefore, before the red InGaN-based chip technology matures, red AlGaInP-based chips are still the main choice for direct light-emitting chips.

However, as the die size of micro LEDs is significantly reduced, the problem of rapid decline in external quantum efficiency (EQE) still exists. The size of micro LED elements needs to be reduced to less than 5-10 μm to achieve a lower cost level, allowing display products to compete with LCD and OLED displays in terms of price. The current EQE level of general-sized blue light LED elements reaches 80%; however, the EQE level of blue light LED components reduced to 5-10 μm is usually only 20% or lower. Such EQE cannot support products that surpass the performance of LCD and OLED displays. Therefore, the low EQE problem of micro LED elements must be effectively resolved to enter the highly competitive consumer market.

The root cause of the low EQE problem lies in the significant defect effects present on the chip side walls; side wall defects include structural damage, foreign contaminants, dangling bonds, and the like. These defects lead to the occurrence of Shockley-Read-Hall (SRH) non-radiative carrier recombination effects on the side wall surface. Related research and analysis have confirmed that these chip side wall defects are mainly caused by the mesa etching of LED chips. The standard etching process for general LED chips uses ICP RIE dry etching, where high-energy plasma, ion bombardment, and chemical reactions leave the defects on the etched side wall surface. The non-radiative recombination effect caused by the foregoing defects exists on the side walls of general-sized LED elements. As the element size is reduced, the proportion of the side wall surface area to the overall surface area of the element increases, and the impact of side wall defects on the overall light emission efficiency of the element becomes more significant. Entering the micro LED size range, both blue and green InGaN-based chips and red AlGaInP-based chips exhibit rapid decline in EQE. The EQE decline problem is particularly significant for AlGaInP-based chips because their surface recombination rate and carrier diffusion length are greater than those of InGaN-based chips.

The low EQE problem faced by micro LED dies mainly stems from the side wall defects caused by chip mesa etching. The main current improvement solution is to compensate for the defects caused by mesa etching with subsequent defect removal or repair processes, such as passivation layer coating or chemical treatment processes on the side wall surface. In the current passivation layer coating process, atomic layer deposition (ALD) of Al₂O₃ has demonstrated the best performance for passivation effectiveness, surpassing other methods such as PECVD and materials like SiO₂. The integration of passivation layers with reflectors to enhance light extraction efficiency (LEE) has also become a key research focus. For the defect removal process after mesa etching, chemical treatments like KOH or NH₄S are commonly employed, while N₂ plasma treatment is another method used for defect repair after mesa etching.

However, all the above technical solutions address side wall defects after they have already formed, requiring additional post-processing steps to remove or repair these defects. These methods inevitably increase process complexity, further limiting manufacturing yield and production efficiency. It is urgent to propose a truly fundamental technical solution, to resolve the problem: How to avoid side wall defects and damage caused by mesa etching in advance, and thoroughly eliminate the decline in EQE.

### SUMMARY

A main objective of the present invention is to provide a micro light-emitting diode with a dielectric frame and a preparation method thereof. Forming a dielectric frame and performing epitaxial growing within the dielectric frame completely avoid defects and damage to the micro LED side walls caused by mesa etching, thereby resolving the problem of rapid decline in external quantum efficiency (EQE) and improving the light emission efficiency of the micro LEDs.

To achieve the above objective, the solution of the present invention is as follows:

The micro light-emitting diode with a dielectric frame in the present invention is formed on an epitaxial substrate. The micro light-emitting diode includes: an n-type doped layer epitaxially formed on the epitaxial substrate; the dielectric frame formed on the epitaxial substrate or the n-type doped layer; a multi-quantum well layer grown within the dielectric frame and located on the n-type doped layer; a p-type doped layer grown within the dielectric frame and located on the multi-quantum well layer; a first metal electrode connected to the p-type doped layer for conducting current to the p-type doped layer; a second metal electrode connected to the n-type doped layer or the epitaxial substrate; and a protective layer covering an outer surface of the dielectric frame and exposing the first metal electrode and the second metal electrode.

The dielectric frame is disposed on the n-type doped layer; the multi-quantum well layer and the p-type doped layer are grown within the first groove of the dielectric frame; and the second metal electrode is disposed outside the dielectric frame, or the dielectric frame beside the stack forms a second groove, and the second metal electrode is disposed in the second groove.

The dielectric frame is disposed on the epitaxial substrate, and the n-type doped layer is located within the dielectric frame.

The n-type doped layer, the multi-quantum well layer, and the p-type doped layer are grown and stacked within the first groove of the dielectric frame. The second metal electrode is disposed outside the dielectric frame, or the dielectric frame beside the stack forms a second groove, and the second metal electrode is disposed in the second groove.

The micro light-emitting diode further includes a transparent current spreading layer, between the p-type doped layer and the first metal electrode, configured to spread the current of the first metal electrode to the p-type doped layer, where the protective layer covers the outer surface of the dielectric frame and the transparent current spreading layer.

When the second metal electrode is connected to the n-type doped layer, the epitaxial substrate is a sapphire substrate, the n-type doped layer is made of n-type gallium nitride (GaN) or n-type indium gallium nitride (InGaN), the multi-quantum well layer is made of indium gallium nitride (InGaN), and the p-type doped layer is made of p-type gallium nitride (GaN) or p-type indium gallium nitride (InGaN). When the second metal electrode is connected to the epitaxial substrate, the epitaxial substrate is a gallium arsenide (GaAs) conductive substrate, the n-type doped layer is made of n-type aluminum gallium indium phosphide (AlGaInP), the multi-quantum well layer is made of aluminum gallium indium phosphide (AlGaInP), and the p-type doped layer is made of p-type aluminum gallium indium phosphide (AlGaInP).

An inner wall of the dielectric frame is inclined inward from top to bottom, or an outer wall of the dielectric frame is inclined outward from top to bottom.

The dielectric frame is made of at least one of silicon dioxide (SiO₂) and silicon nitride (Si₃N₄), a transparent current spreading layer is formed between the p-type doped layer and the first metal electrode, the transparent current spreading layer is made of indium tin oxide (ITO), the protective layer includes a passivation layer or a reflector, the passivation layer is made of one of aluminum oxide (Al₂O₃) and silicon dioxide (SiO₂), and the reflector is a distributed Bragg reflector (DBR).

The present invention provides a preparation method of a micro light-emitting diode with a dielectric frame, including the following steps:
S1: forming, on an epitaxial substrate, an n-type doped layer and a dielectric layer, and performing first etching on the dielectric layer to form a first groove, where the n-type doped layer is under the dielectric layer or the n-type doped layer is in the first groove;
S2: growing a multi-quantum well layer on the n-type doped layer, where the multi-quantum well layer is located within the first groove;
S3: growing a p-type doped layer on the multi-quantum well layer, where the p-type doped layer is located within the first groove;
S4: performing second etching on the dielectric layer at a periphery of the first groove to form the dielectric frame; and
S5: forming a first metal electrode conducting current to the p-type doped layer; forming a second metal electrode on one of the n-type doped layer and the epitaxial substrate; and forming a protective layer, where the protective layer covers an outer surface of the dielectric frame and exposes the first metal electrode and the second metal electrode.

In step S1, the n-type doped layer is first formed on the epitaxial substrate, and the dielectric layer is then formed on the n-type doped layer.

Before or after step S4, a step is added: forming a transparent current spreading layer on the p-type doped layer, such that the transparent current spreading layer is between the p-type doped layer and the first metal electrode, to spread the current of the first metal electrode to the p-type doped layer.

With the use of the above solution, in the present invention, an amorphous dielectric layer is used, such as silicon dioxide (SiO₂) or silicon nitride (Si₃N₄), to first create an appropriate amorphous dielectric layer frame, and then sequentially perform epitaxial growth within the frame. This method can replace the micro LED structure manufactured by mesa etching, completely avoiding the effects of damage and defects to the micro LED side walls caused by mesa etching, thereby fundamentally resolving the problem of rapid decline in EQE of micro LEDs. This not only resolves the problem of rapid EQE decline but also effectively improves the light emission efficiency of the micro LEDs. Moreover, the process improvements also enhance product yield and production efficiency.

According to the present invention, forming a dielectric frame with a predetermined layout allows different color micro LED dies to be epitaxially grown within different frames on the same substrate, thus enabling the formation of multi-color dies on a single substrate to form full-color pixels.

The present invention can resolve the stress problems in the manufacturing and usage processes by selecting the shape of the dielectric frame, improving the light extraction efficiency. Specifically, a dielectric frame with an inner wall inclined inward from top to bottom can be selected to alleviate the stress generated in the multi-quantum well layer and p-type doped layer during epitaxial growth. Additionally, adopting a dielectric frame with an outer side inclined outward from top to bottom can further enhance light extraction efficiency.

### BRIEF DESCRIPTION OF DRAWINGS

FIG. 1 is a flowchart of a preparation method according to a first preferred embodiment of the present invention.

FIGS. 2A to 2E are structural cross-sectional views of intermediate steps in a preparation process of FIG. 1.

FIG. 2F is a structural cross-sectional view according to the first preferred embodiment of the present invention.

FIG. 3 is a structural cross-sectional view according to a second preferred embodiment of the present invention.

FIG. 4 is a structural cross-sectional view according to a third preferred embodiment of the present invention.

FIG. 5 is a structural cross-sectional view according to a fourth preferred embodiment of the present invention.

FIG. 6 is a structural cross-sectional view according to a fifth preferred embodiment of the present invention.

Description of numeral references

| | |
|---|---|
| 1, 1′, 2, 3, 4 | micro light-emitting diodes |
| 11, 11′, 21, 31, 41 | epitaxial substrate |
| 12, 12′, 22, 32, 42 | dielectric frame |
| 13, 13′, 23, 33, 43 | n-type doped layer |
| 14, 14′, 24, 34, 44 | multi-quantum well layer |
| 15, 15′, 25, 35, 45 | p-type doped layer |
| 16, 16′, 26, 36, 46 | transparent current spreading layer |
| 17, 17′, 27, 37, 47 | first metal electrode |
| 18, 18′, 28, 38, 48 | second metal electrode |
| 19, 19′, 29, 39, 49 | protective layer |
| 120 | dielectric layer |
| 121 | first groove |
| 122 | second groove |

### DESCRIPTION OF EMBODIMENTS

The following describes the implementations of the present invention with reference to specific embodiments. Those skilled in the art can easily understand other advantages and effects of the present invention from the disclosed content of the specification. The structures, proportions, sizes, and the like shown in the accompanying drawings are only for the purpose of illustrating the content disclosed in the specification, to facilitate understanding and reading by those skilled in the art, and are not intended to limit the implementation conditions of the present invention. They do not have technical substantive significance. Any structural modifications, proportional changes, or size adjustments that do not affect the effectiveness and objectives of the present invention shall still fall within the scope of the present invention. The terms such as “one”, “two”, and “above” used in this specification are also for the convenience of understanding and are not intended to limit the scope of implementation of the present invention. Changes or adjustments in relative relationships without substantial changes in technical content are also considered within the scope of implementation of the present invention.

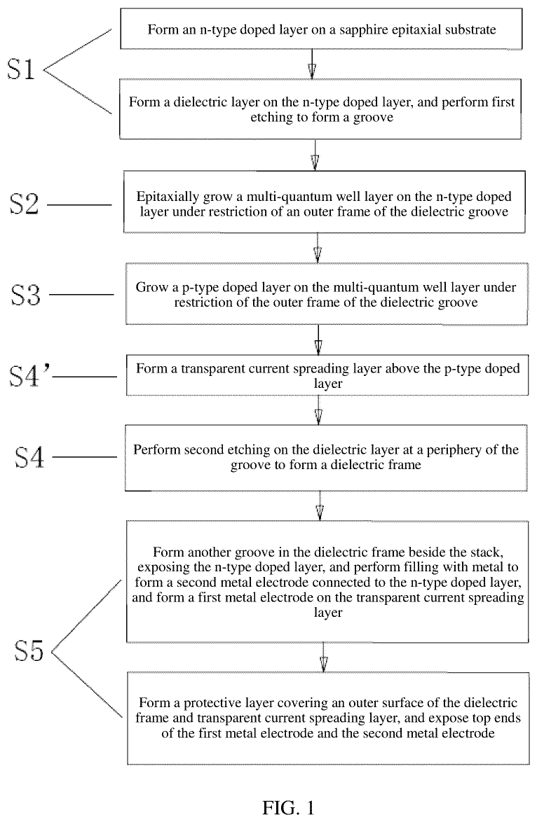

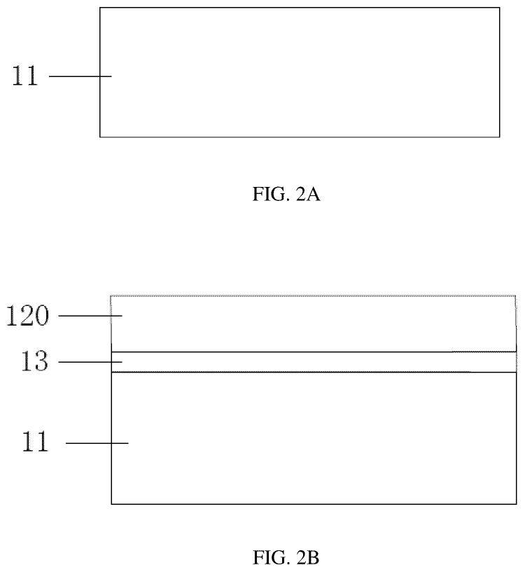

As shown in FIG. 1, a preparation method of a micro light-emitting diode 1 with a dielectric frame according to a first embodiment of the present invention is as follows: First, in step S1, as shown in FIG. 2A, an n-type doped layer 13 of n-type gallium nitride (GaN) or n-type indium gallium nitride (InGaN) is formed on an epitaxial substrate 11, for example, sapphire. Then, as shown in FIG. 2B, a dielectric layer 120 of, for example, SiO₂ or silicon nitride (Si₃N₄) is formed on the n-type doped layer 13. As shown in FIG. 2C, first etching is performed on the dielectric layer 120 to form the first groove 121. After the dielectric layer 120 is etched to form the first groove 121, the remaining part forms the peripheral wall for limiting the subsequent epitaxial structure.

Then in step S2, according to the limitation of the outer frame of the first groove 121, a multi-quantum well layer 14 of, for example, indium gallium nitride (InGaN) material is epitaxially grown as the main light-emitting layer within the first groove 121 on the n-type doped layer 13. Step S3 is also limited by the first groove 121. As shown in FIG. 2D, a p-type doped layer 15 of p-type gallium nitride (GaN) or p-type indium gallium nitride (InGaN) is grown on the multi-quantum well layer 14. In this case, the p-type doped layer 15 is flush with the dielectric frame 12 in the height direction. To horizontally spread the current and prevent the electron-hole pair recombination position from being too concentrated under the first metal electrode 17, which otherwise causes shading issues, step S4′ is added to form a transparent current spreading layer 16 of, for example, indium tin oxide (ITO) above the p-type doped layer 15.

Next, in step S4, as shown in FIG. 2E, second etching is performed on the dielectric layer 120 at a periphery of the first groove 121 to form the dielectric frame 12. Then, in step S5, a second groove 122 is formed in the dielectric frame 12 beside the stack, exposing the n-type doped layer 13. Filling is performed with metal to form a second metal electrode 18 connected to the n-type doped layer 13, and a first metal electrode 17 is formed on the transparent current spreading layer 16, thus forming a complete LED circuit. Finally, a protective layer 19 is formed, covering an outer surface of the dielectric frame 12 and the transparent current spreading layer 16, and exposing the top ends of the first metal electrode 17 and the second metal electrode 18 for connection. The protective layer 19 may include a passivation layer or a reflector, where the passivation layer is made of one of aluminum oxide (Al₂O₃) and silicon dioxide (SiO₂), and the reflector is a distributed Bragg reflector (DBR) and configured to enhance the light output efficiency of the micro light-emitting diode 1.

Obviously, because the multi-quantum well layer 14 and the p-type doped layer 15 are epitaxially grown within the dielectric frame 12, the mesa etching technique and the associated side wall defects are eliminated, thereby overcoming the technical problem of decline in EQE and effectively improving the light emission efficiency of the micro light-emitting diode.

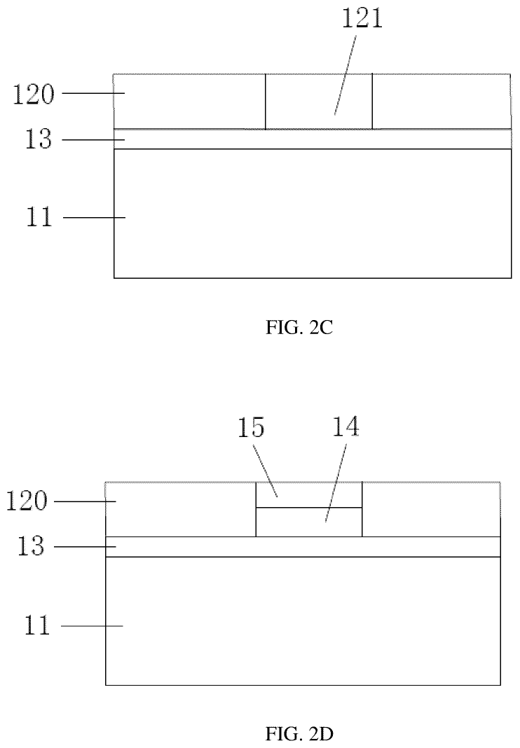

Certainly, as those skilled in the art can easily understand, during subsequent processing, if isolation, passivation, mechanical strength, or the like is required, a wider dielectric frame needs to be retained for support. As shown in FIG. 3, a micro light-emitting diode 1′ with a dielectric frame in a second embodiment of the present invention has structures: an epitaxial substrate 11′, an n-type doped layer 13′, a dielectric frame 12′, a multi-quantum well layer 14′, a p-type doped layer 15′, a transparent current spreading layer 16′, a first metal electrode 17′, a second metal electrode 18′, and a protective layer 19′, which are the same as those in the first embodiment. After step S3, step S4 is directly performed; second etching is performed on the dielectric layer at a periphery of the first groove 121 to form the dielectric frame 12′. The width of the dielectric frame 12′ is narrower than that of the dielectric frame 12 in the previous embodiment. The protective layer 19′ covers the outer side of the dielectric frame 12′, and the second metal electrode 18′ is located outside the dielectric frame 12′, thus extending lower in the height direction.

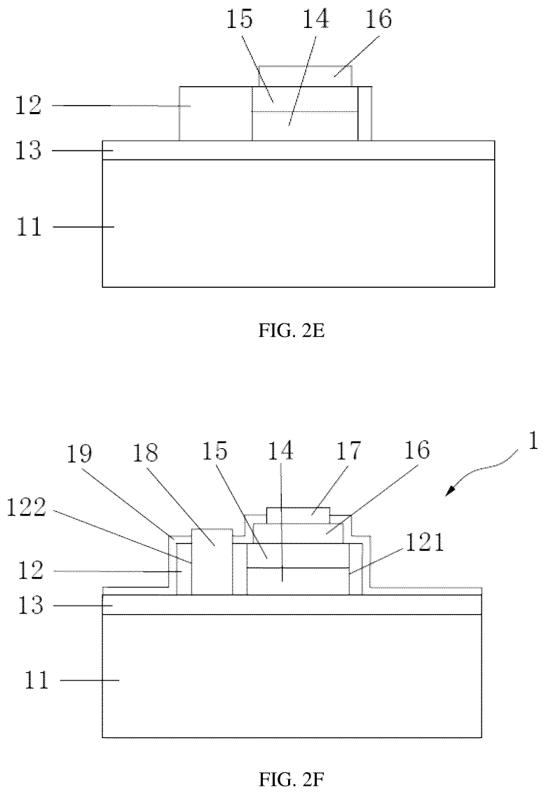

Furthermore, in the above embodiments, the dielectric frame is formed on the n-type doped layer. However, as those skilled in the art can easily understand, as shown in FIG. 4, in a third preferred embodiment of a micro light-emitting diode 2 with a dielectric frame, a dielectric layer may also be directly formed on an epitaxial substrate 21, such as sapphire. First etching is performed on the dielectric layer to form the first groove 121, allowing the n-type doped layer 23, the multi-quantum well layer 24, and the p-type doped layer 25 that are epitaxially grown subsequently to be epitaxially grown within the range defined by the dielectric first groove 121. Then second etching is performed on the dielectric layer at the periphery of the first groove 121 to form the dielectric frame 22. The transparent current spreading layer 26 is located on the p-type doped layer 25 and is higher than the dielectric frame 22. The multi-quantum well layer 24 and the p-type doped layer 25 are partially etched away to expose the n-type doped layer 23, and the dielectric layer is used to fill the etched part. Then, a second groove 122 is formed within the dielectric frame 22 and the filled dielectric layer, exposing the n-type doped layer 23 in the second groove 122. The first metal electrode 27 is formed through connection on the transparent current spreading layer 26, and the second metal electrode 28 fills the second groove 122 and is connected to the n-type doped layer 23. The protective layer 29 covers the outer surface of the dielectric frame 22 and the transparent current spreading layer 26, exposing the first metal electrode 27 and the second metal electrode 28.

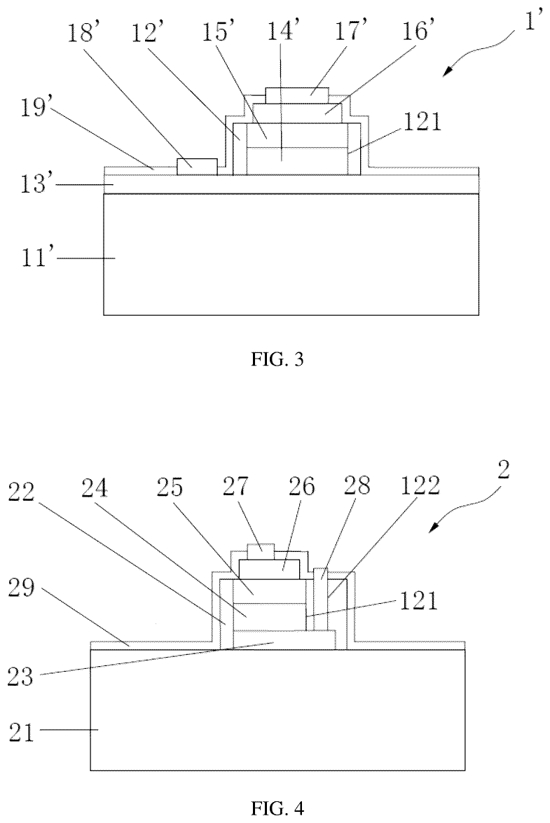

Referring to FIG. 5, a fourth embodiment of the present invention provides a micro light-emitting diode 3 with a dielectric frame, including: a gallium arsenide (GaAs) conductive substrate as an epitaxial substrate 31; an n-type doped layer 33 epitaxially grown on the epitaxial substrate 31; a dielectric layer formed on the epitaxial substrate 31, where the dielectric layer is subjected to first etching to form a first groove 121, and the n-type doped layer 33 is located in the dielectric first groove 121; a multi-quantum well layer 34 grown in the dielectric first groove 121 and located on the n-type doped layer 33; a p-type doped layer 35 grown in the dielectric first groove 121 and located on the multi-quantum well layer 34, where as in the first embodiment, second etching is performed on the dielectric layer at the periphery of the first groove 121 to form a dielectric frame 32; a transparent current spreading layer 36 located on the p-type doped layer 35, where as in the first embodiment, a second groove 122 is formed in the dielectric frame 12 beside the stack; a first metal electrode 37 connected to the transparent current spreading layer 36; a second metal electrode 38 filling the second groove 122 and connected to the epitaxial substrate 31; and a protective layer 39, covering the outer surface of the dielectric frame 32 and the transparent current spreading layer 36 and exposing the first metal electrode 37 and the second metal electrode 38. In this example, the inner wall of the dielectric frame 32 is inclined inward from top to bottom, thereby relieving the stress of the multi-quantum well layer 34 and the p-type doped layer 35 during epitaxy.

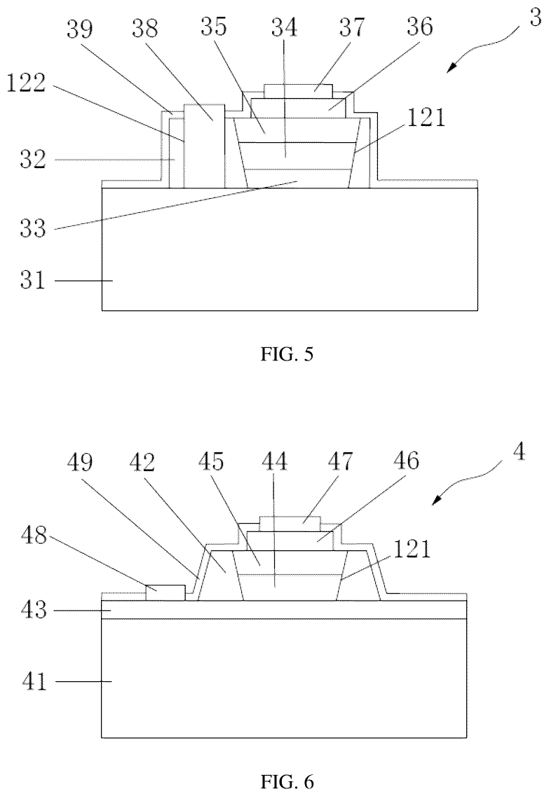

Referring to FIG. 6, a fifth embodiment of the present invention provides a micro light-emitting diode 4 with a dielectric frame, including: an epitaxial substrate 41; an n-type doped layer 43 epitaxially grown on the epitaxial substrate 41; a dielectric layer formed on the n-type doped layer 43, where the dielectric layer is subjected to first etching to form a first groove 121; a multi-quantum well layer 44 grown in the dielectric first groove 121 and located on the n-type doped layer 43; a p-type doped layer 45 grown in the dielectric first groove 121 and located on the multi-quantum well layer 44; a transparent current spreading layer 46 located on the p-type doped layer 45, where as in the first embodiment, the dielectric layer at the periphery of the first groove 121 is subjected to second etching to form the dielectric frame 42; a first metal electrode 47 connected to the transparent current spreading layer 46; a second metal electrode 48 connected to the n-type doped layer 43; and a protective layer 49 covering the outer surface of the dielectric frame 42, the n-type doped layer 43, and the transparent current spreading layer 46, and exposing the first metal electrode 47 and the second metal electrode 48. In this example, the inner wall of the dielectric frame 42 is inclined inward from top to bottom, relieving the stress of the multi-quantum well layer 44 and the p-type doped layer 45 during epitaxy, and the outer side of the dielectric frame 42 is also inclined outward from top to bottom, thereby improving light extraction efficiency.

Although in the above embodiments, the transparent current spreading layers are formed on the p-type doped layers, those skilled in the art can easily understand that if the first metal electrode itself can distribute and spread the current evenly, it is not necessary to dispose the above transparent current spreading layers. This still falls within the scope of the present invention. Moreover, after the micro LED dies are manufactured on the epitaxial substrate, the dies can be separated from the epitaxial substrate by laser lift off (LLO), epitaxial substrate grinding, or wet etching methods, and then the micro LED dies or micro LED die arrays originally formed on the epitaxial substrate can be transferred. Therefore, the scope of the present invention also includes micro LED dies that are present on the epitaxial substrate or have been transferred from the epitaxial substrate. Additionally, SiO₂ can be pre-formed as a stop layer for frame etching at the bottom of the Si₃N₄ dielectric frame, and then SiO₂ inside the frame is removed by wet etching to reduce the dry etching damage of the n-epitaxial layer. Any measures within the scope of epitaxial processes aimed at enhancing the light-emitting efficiency or characteristics of the element can be compatible with the dielectric frame process of the present invention, such as super lattice, electron blocking layer (EBL), or cladding layer, or special heterostructure material layers are introduced in the multi-quantum well structure for stress effects or band engineering purposes. Such variations are still included in the scope of the following patent claims of the present invention.

In summary, the micro light-emitting diode with a dielectric frame and the preparation method thereof in the present invention include this dielectric frame, which can avoid defects and damage to the side walls of the micro light-emitting diode caused by mesa etching, thereby resolving the problem of rapid decline in external quantum efficiency and improving the light emission efficiency of the micro light-emitting diode. Furthermore, the inner wall of the dielectric frame is inclined inward from top to bottom, which can relieve the stress of the multi-quantum well layer and the p-type doped layer during epitaxy. Additionally, the outer side of the dielectric frame is inclined outward from top to bottom, which is beneficial for improving light extraction efficiency.

It should be noted that the key to this case is that the dielectric frame 12 is formed by two etchings on the dielectric layer. In this way, in the present invention, a single independent micro light-emitting diode can be formed. Moreover, as the size of the dielectric frame 12 is controlled, the size of the micro light-emitting diode can be controlled, such that the micro light-emitting diode is applicable to mass transfer technology, better meeting the needs of practical assembly. When the epitaxial substrate is made of gallium arsenide, the second metal electrode 18 can be formed within the dielectric frame 12 or outside the dielectric frame 12. The transparent current spreading layer 16 may be formed before the second etching to form the dielectric frame 12 or after the second etching to form the dielectric frame 12. Additionally, in step S5, the formation sequence of the first metal electrode 17, the second metal electrode 18, and the protective layer 19 is not restricted by the specific embodiment. The first metal electrode 17 and the second metal electrode 18 may be formed first, followed by covering the protective layer 19; or the protective layer 19 may be covered first and partially removed, and then the first metal electrode 17 and the second metal electrode 18 can be formed; or one of the first metal electrode 17 and the second metal electrode 18 may be formed first, followed by covering the protective layer 19, and then forming the other of the first metal electrode 17 and the second metal electrode 18; or other sequences not listed herein are used. This is elaborated herein.

The above embodiments are merely illustrative of the principles and effectiveness of the present invention and are not intended to limit the present invention. Even so, any person skilled in the art can make modifications to the above embodiments without departing from the spirit and scope of the present invention. Therefore, the scope of protection of the present invention should be as listed in the claims of the patent application.

1. A micro light-emitting diode with a dielectric frame, formed on an epitaxial substrate, wherein the micro light-emitting diode comprises:
an n-type doped layer epitaxially formed on the epitaxial substrate;
the dielectric frame formed on the epitaxial substrate or the n-type doped layer;
a multi-quantum well layer grown within the dielectric frame and located on the n-type doped layer;
a p-type doped layer grown within the dielectric frame and located on the multi-quantum well layer;
a first metal electrode connected to the p-type doped layer to conduct current;
a second metal electrode connected to the n-type doped layer or the epitaxial substrate; and
a protective layer covering an outer surface of the dielectric frame and exposing the first metal electrode and the second metal electrode.

2. The micro light-emitting diode with a dielectric frame according to claim 1, wherein the dielectric frame is disposed on the epitaxial substrate, and the n-type doped layer is located within the dielectric frame.

3. The micro light-emitting diode with a dielectric frame according to claim 1, further comprising a transparent current spreading layer between the p-type doped layer and the first metal electrode, wherein the protective layer covers the outer surface of the dielectric frame and the transparent current spreading layer.

4. The micro light-emitting diode with a dielectric frame according to claim 1, wherein when the second metal electrode is connected to the n-type doped layer, the epitaxial substrate is a sapphire substrate, the n-type doped layer is made of n-type gallium nitride or n-type indium gallium nitride, the multi-quantum well layer is made of indium gallium nitride, and the p-type doped layer is made of p-type gallium nitride or p-type indium gallium nitride.

5. The micro light-emitting diode with a dielectric frame according to claim 1, wherein when the second metal electrode is connected to the epitaxial substrate, the epitaxial substrate is a gallium arsenide conductive substrate, the n-type doped layer is made of n-type aluminum gallium indium phosphide, the multi-quantum well layer is made of aluminum gallium indium phosphide, and the p-type doped layer is made of p-type aluminum gallium indium phosphide.

6. The micro light-emitting diode with a dielectric frame according to claim 1, wherein an inner wall of the dielectric frame is inclined inward from top to bottom, or an outer wall of the dielectric frame is inclined outward from top to bottom.

7. The micro light-emitting diode with a dielectric frame according to claim 1, wherein the dielectric frame is made of at least one of silicon dioxide or silicon nitride, a transparent current spreading layer is formed between the p-type doped layer and the first metal electrode, the transparent current spreading layer is made of indium tin oxide, the protective layer comprises a passivation layer or a reflector, the passivation layer is made of one of aluminum oxide or silicon dioxide, and the reflector is a distributed Bragg reflector.

8. A preparation method of a micro light-emitting diode with a dielectric frame, comprising the following steps:
S1: forming, on an epitaxial substrate, an n-type doped layer and a dielectric layer, and performing first etching on the dielectric layer to form a first groove, wherein the n-type doped layer is under the dielectric layer or the n-type doped layer is in the first groove;
S2: growing a multi-quantum well layer on the n-type doped layer, wherein the multi-quantum well layer is located within the first groove;
S3: growing a p-type doped layer on the multi-quantum well layer, wherein the p-type doped layer is located within the first groove;
S4: performing second etching on the dielectric layer at a periphery of the first groove to form the dielectric frame; and
S5: forming a first metal electrode conducting current to the p-type doped layer; forming a second metal electrode on one of the n-type doped layer or the epitaxial substrate; and forming a protective layer, wherein the protective layer covers an outer surface of the dielectric frame and exposes the first metal electrode and the second metal electrode.

9. The preparation method of a micro light-emitting diode with a dielectric frame according to claim 8, wherein in the step S1, the n-type doped layer is first formed on the epitaxial substrate, and the dielectric frame is then formed on the n-type doped layer.

10. The preparation method of a micro light-emitting diode with a dielectric frame according to claim 8, wherein, before or after the step S4, the preparation method further comprises:
S4′: forming a transparent current spreading layer on the p-type doped layer.
